(19) United States
(12) Patent Application Publication
(10) Pub. No.: US 2004/0075159 A1
(43) Pub. Date: Apr. 22, 2004

(54) Nanoscopic tunnel

(75) Inventor: Bernhard Vogeli, Boston, MA (US)

Correspondence Address: HALE AND DORR, LLP, 60 STATE STREET, BOSTON, MA, 02109

(73) Assignee: Nantero, Inc.

(21) Appl. No.: 10/272,683

(22) Filed: Oct. 17, 2002

(51) Int. Cl. H01L 29/06; H01L 21/76; H01L 23/544

(52) U.S. Cl. 257/618; 257/622; 257/623; 438/978; 257/797; 438/401; 438/462; 438/975

(57) ABSTRACT

A nanoscopic tunnel is disclosed. The tunnel can be formed in or on a substrate, such as a semiconductor.

### BACKGROUND

1. Technical Field

The invention relates generally to patterning substrates, such as semiconductors, and in particular to forming one or more nanoscopic tunnels in or on a substrate.

2. Discussion of Related Art

Various methods are known for forming patterns in or on the surface of a substrate. For example, U.S. Pat. No. 4,896,044 (Li et al.) discloses a method of forming depressions on the surface of a conducting substrate, and U.S. Pat. No. 5,880,004 (Ho) reports a method of providing a shallow trench within a semiconductor substrate. A method of forming cave-like pores on the sides of prefabricated blocks also has been reported, in which an exposed porous surface is formed on the sidewall of an etched step in a shallow layer at the surface of a substrate (“Localized and Directional Lateral Growth of Carbon Nanotubes from a Porous Template,” Wind et al., IBM, unpublished). The cave-like pores are randomly located and have random cross-sectional sizes. The pores are openings that extend into the substrate but are closed on the interior end. Similarly, a via used in semiconductor manufacturing is an opening in the surface of a substrate that extends vertically straight down into the substrate and has a closed end in the interior of the substrate. The via is formed by etching straight down into the substrate surface. British Patent Application No. 2,364,933 (Shin et al.) discloses the use of vertical apertures extending down into or through a substrate and an overlying layer in methods of growing carbon nanotubes. Methods also are known for fabricating semiconductor devices that contain air gaps to reduce capacitance and prevent cross talk between metal leads (U.S. patent application Ser. No. 2002/0081787 (Kohl et al.); U.S. Pat. No. 6,165,890 (Kohl et al.); U.S. Pat. No. 5,461,003 (Havemann et al.); U.S. Pat. No. 5,324,683 (Fitch et al.); U.S. Pat. No. 4,987,101 (Kaanta et al.)).

A need exists in the art for nanoscopic tunnels and methods of making the same.

### SUMMARY

The present invention provides nanoscopic tunnels and methods of making the same. One aspect of the invention provides an article defining a nanoscopic covered passage. The passage has a first end, a second end, and an opening at each end.

In some embodiments, the passage has a width between about 20 nm and about 200 nm and a height between about 1 nm and about 200 nm. In particular embodiments, the passage has a width between about 20 nm and about 100 nm and a height between about 1 nm and about 100 nm. In some embodiments, the passage has a length between about 20 nm and about 12 inches. In certain embodiments, the passage has a length between about 1 μm and about 12 inches. In particular embodiments, the passage has a length between about 5 μm and about 12 inches. In specific embodiments, the passage has a length of about 4 inches.

In some embodiments, the passage is located in a semiconductor wafer. In other embodiments, the passage is located on a semiconductor wafer. In certain embodiments, the passage defines a three-dimensional path. In some embodiments, the passage and has a transverse cross-section with a controlled height and width. In certain embodiments, the height and width are each respectively substantially uniform over the entire passage. In other embodiments, the passage is tapered.

In some embodiments, the article includes a substrate, a covering layer resting on the substrate, and a space between the covering layer and the substrate. The space between the covering layer and the substrate defines the passage. In certain embodiments, the passage is embedded by the covering layer. In other embodiments, the passage is raised above the substrate. In particular embodiments, the passage defines a path that is not perpendicular to a major surface of the substrate.

In some embodiments, the substrate includes a semiconductor. In certain embodiments, the substrate is a semiconductor wafer and the passage has a length approximately equal to the length of the wafer. In some embodiments, the substrate includes silicon dioxide. In other embodiments, the substrate includes a metal oxide. In certain embodiments, the covering layer includes a metal. In other embodiments, the covering layer includes silicon oxide.

Another aspect of the invention provides an article defining a tunnel having a width between about 20 nm and about 200 nm and a height between about 1 nm and about 200 nm. The width and the height are controlled.

Still another aspect of the invention provides an article comprising a substrate, a covering layer resting on the substrate, and a space between the covering layer and the substrate. The covering layer and the substrate are each respectively substantially homogeneous materials. The space between the covering layer and the substrate defines a nanoscopic tunnel having a transverse cross-section with a controlled height and width.

### BRIEF DESCRIPTION OF THE DRAWING

In the Drawing,

FIGS. 1A-C illustrate transverse cross-sectional views of nanoscopic tunnels according to certain embodiments of the invention; and

FIGS. 2A-4 illustrate acts of making nanoscopic tunnels according to certain embodiments of the invention.

### DETAILED DESCRIPTION

Formation of nanoscopic tunnels would be useful in various applications, for example, in manufacturing nanoscopic wires, circuits, and memory devices. Nanoscopic tunnels or capillaries would be useful for nanoscale extrusion of long molecules such as DNA. Nanoscopic tunnels would provide a useful structure for the directed growth of nanotubes. Advantageously, additional layers and structures could be provided on top of embedded tunnels, unlike open structures, such as channels. Therefore, a need exists in the art for nanoscopic tunnels and methods of making the same.

Certain embodiments of the invention provide nanoscopic tunnels. The term “tunnel,” as used herein, refers to a covered passage having at least one opening. The opening and the body of the passage are created either concurrently or at different times. In some embodiments, the tunnel is a covered passage having an opening at each end. “Nanoscopic,” as used herein, means having at least one dimension, e.g., width, height, or extent, that is between about 1 nm and about 1000 nm. In certain embodiments, a nanoscopic tunnel has at least one dimension, e.g., height, that is on the order of nanometers and about as high as thin film limits, e.g., monolayer deposition. In at least some embodiments, one or more nanoscopic tunnels is located in or on a substrate, such as a semiconductor, a metal, or an insulator. Non-limiting examples of suitable substrate materials include silicon, silicon dioxide, gallium arsenide, and metal oxides.

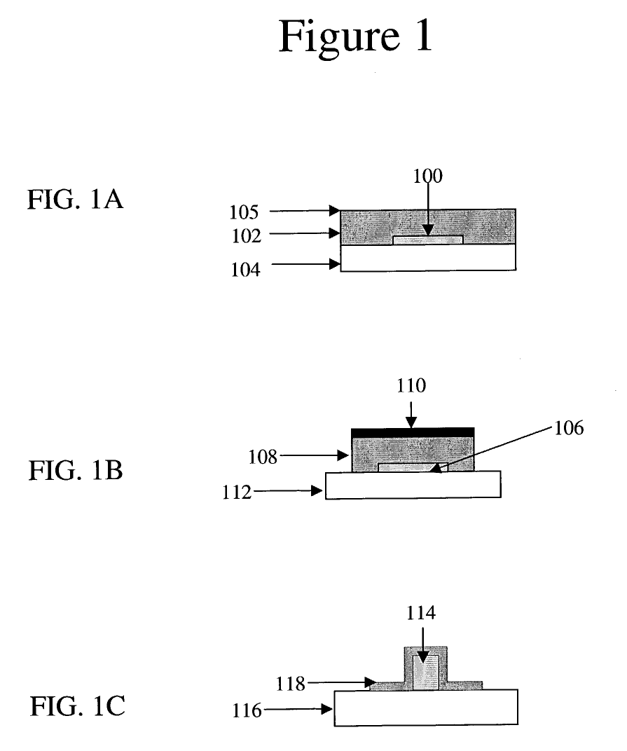

FIGS. 1A-C illustrate transverse cross-sectional views of structures including nanoscopic tunnels according to certain embodiments of the invention. FIG. 1A depicts a tunnel 100 defined by a layer 102 and a substrate 104. The layer 102 provides a covering layer over the tunnel 100, defining a roof and side walls, while the substrate 104 defines a floor. The passage of the tunnel 100 is defined by a space between the covering layer 102 and the substrate 104. Advantageously, the tunnel 100 is embedded within the layer 102, so that the exposed top surface 105 of the layer 102 provides a broad planar region on which further layers and structures easily can be provided as desired.

FIG. 1B depicts a tunnel 106 embedded by a layer 108 that rests on a substrate 112 and is covered by a mask 110. The passage of the tunnel 106 is defined by a space between the covering layer 108 and the substrate 112. The layer 108 has been patterned, for example, by lithography and etching using the mask 10, so that the layer 108 does not cover the entire substrate 112.

FIG. 1C depicts a tunnel 114 that is surrounded by a covering layer 118, which rests on a substrate 116. The passage of the tunnel 114 is defined by a space between the covering layer 118 and the substrate 116. The tunnel walls and roof are raised above the top surface of the substrate 116. The figures illustrate that a “covering layer,” as used herein, refers to not only a planar or substantially planar stratified zone (e.g., FIG. 1A), but also a non-planar tunnel-surrounding structure (e.g., FIG. 1C). FIGS. 1A-C depict transverse cross-sections of tunnels that extend horizontally across a substrate. As described in greater detail below, in various embodiments, the path defined by a tunnel passage is defined as desired depending on the application. However, in certain embodiments, the tunnel path typically includes at least some horizontal component.

In at least some embodiments, the location, orientation, dimensions, and other physical characteristics of a nanoscopic tunnel are precisely controlled, for example, using lithographic patterning and thin film techniques. Useful lithographic sources include any of those known in the art, for example, light, including photolithography, x-rays, electrons, or ions. In certain embodiments, the tunnel width and extent are determined by the lithographic techniques utilized in tunnel formation. For example, electron beams are known in the art to provide very fine detail. Current technology using electron beam lithography allows for formation of tunnels having lengths and/or widths below about 30 nm, for example, about 22 nm. In particular embodiments, phase shift electron beam lithography is used to produce very short or narrow tunnels. It is anticipated that future improvements in lithographic techniques will allow for the formation of even finer dimensions. The length and width of a tunnel are defined as desired according to the application. In some embodiments, the tunnel length is between about 20 nm and about 12 inches, for example, between about 100 nm and about 8 inches long. In certain embodiments, the tunnel length is between about 1 μm and about 12 inches, for example, between about 5 μm and about 12 inches. In particular embodiments, a tunnel is about 4 inches long. The tunnel length may extend across an entire semiconductor wafer. In some embodiments, the tunnel width is between about 20 nm and about 1000 nm, for example, between about 20 nm and about 200 nm, or between about 20 nm and about 100 nm wide. In particular embodiments, the tunnel width is about 150 nm.

As described in greater detail below, a tunnel passage often is created by removal of a sacrificial tunnel template layer that defines the shape of the tunnel volume. Accordingly, the height of the tunnel is affected by the height of the tunnel template, which in turn is affected by the method used to create the sacrificial layer, e.g., deposition or growth. In certain embodiments, the tunnel height is defined by a thin film process. Using current technology, thin film processes are capable of producing smaller dimensions than lithographic techniques, allowing for dimensions on the order of nanometers, e.g., as small as a monolayer of atoms. In certain embodiments, the tunnel height is approximately equal to the height of a monolayer of sacrificial material. In particular embodiments, the tunnel height is between about 1 nm and about 1000 nm, for example, between about 1 nm and about 200 nm, between about 1 nm and about 100 nm, or between about 5 nm and about 100 nm high. In specific embodiments, the tunnel height is about 5 nm.

The tunnel shape, i.e., the shape defined by a cross-section of the tunnel passage taken perpendicular to the length of the passage, is defined as desired depending upon the application. For example, the passage cross-section is approximately square, rectangular, triangular, trapezoidal, circular, or ovoid. In at least some embodiments, techniques such as lithographic and thin film processes are used to produce tunnels having controlled dimensions and shapes, in contrast with structures created by other methods that yield random dimensions and cross-sections. In some instances, the tunnel height and width are each substantially uniform along the extent of the tunnel passage. In other instances, the tunnel height and/or width vary along the extent of the tunnel passage. In certain embodiments, the tunnel is tapered, i.e., is designed to have a height and/or width that gradually increases or decreases from one end of the tunnel passage to the other. As a non-limiting example, the tunnel passage has a width of about 2 μm at one end, and tapers to have a width of about 22 nm at the other end. Such a tapered tunnel could be useful, for example, in DNA extrusion.

The path defined by the tunnel passage similarly is defined as desired depending upon the application, for example, using lithographic and processing techniques. In at least some embodiments, the tunnel defines a path that has at least some horizontal component, i.e., it does not define a straight vertical path through a substrate and/or one or more overlying layers. In this context, “horizontal” means parallel to a major surface of the substrate, while “vertical” means perpendicular to a major surface of the substrate. The term “major surface” refers to the surface (or surfaces) of the substrate having the greatest surface area. Generally, the major surface is recognized by those of skill in the art as the top surface upon which any overlying layers are provided, and upon which any structures, circuitry, etc. are manufactured. In certain embodiments, the tunnel is straight. In other embodiments, the tunnel is curved. In some embodiments, the tunnel has bends or turns. The bends and turns may be horizontal or vertical. In certain embodiments, the tunnel defines a three-dimensional path, i.e., a path having both horizontal and vertical components.

Certain embodiments of the invention provide methods of making nanoscopic tunnels. In particular embodiments, a substrate is provided and a tunnel template is provided on the substrate. A covering layer is provided over the tunnel template and the substrate. The tunnel template is then removed, for example, by dissolution or etching, thereby forming a space between the covering layer and the substrate. The space between the covering layer and the substrate defines the nanoscopic tunnel.

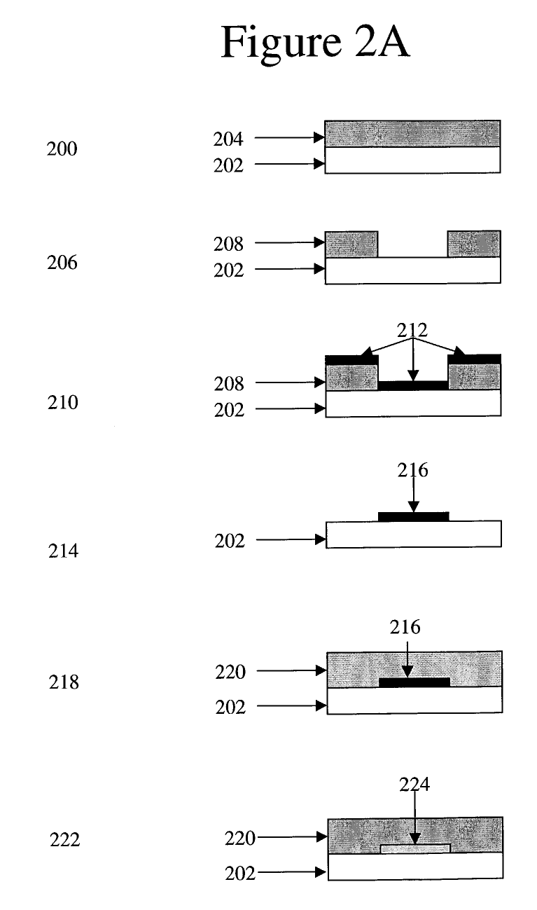

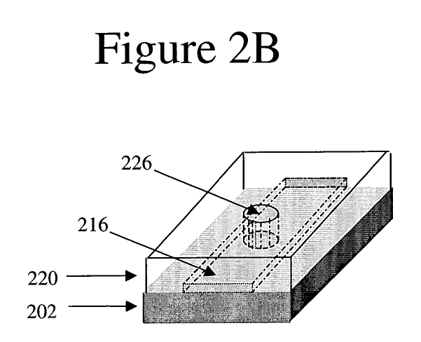

FIGS. 2A-4 illustrate exemplary methods of forming nanoscopic tunnels according to certain embodiments of the invention. Referring to FIG. 2A, a structure 200 is provided including a substrate 202. The substrate material is chosen based on the desired physical characteristics of the final product. In some embodiments, the substrate is made up of multiple layers of different materials as desired. Suitable substrate materials include semiconductors, conductors, and insulators. Non-limiting examples include silicon, e.g., single crystalline silicon, gallium arsenide, silicon on sapphire (SOS), epitaxial formations, germanium, germanium silicon, diamond, silicon on insulator (SOI) material, selective implantation of oxygen (SIMOX) substrates, salts of groups III and V or II and VI of the periodic table, wet or dry silicon dioxide (SiO₂), nitride materials, tetraethylorthosilicate (TEOS) based oxides, borophosphosilicate glass (BPSG), phosphosilicate glass (PSG), borosilicate glass (BSG), oxide-nitride-oxide (ONO), tantalum pentoxide (Ta₂O₅), plasma enhanced silicon nitride, titanium oxide, oxynitride, germanium oxide, spin on glass (SOG), chemical vapor deposited (CVD) dielectrics, grown oxides, metals such as gold, platinum, molybdenum, tungsten, and copper, any alloys, or metal oxides.

A layer of resist 204 is provided on the substrate 202. Suitable materials for the resist layer 204 include those materials known in the art to be suitable for lithographic use, including, but not limited to, commercially available resists such as poly(methylmethacrylate) (PMMA), and negative electron beam resists such as NEB 22 and NEB 30 (Sumitomo Chemical Co., Tokyo, Japan). In certain embodiments, the resist 204 is a photoresist. Lithography is used to create a pattern in the resist layer 204. In some embodiments, the pattern is defined by a mask placed over the resist 204. In other embodiments, projection lithography is used. Useful lithographic sources include any of those known in the art, for example, light, including x-rays, electrons, or ions. After treatment with the lithographic source, patterned areas of the resist layer 204 are removed, producing structure 206 having patterned resist layer 208. Various techniques are known in the art for selectively removing portions of a layer patterned by lithography. For example, non-solidified regions of a patterned photoresist (i.e., the unexposed regions of a negative photoresist or the exposed regions of a positive photoresist) are removed using a development process, such as, for example, wet etching, dry etching, or supercritical etching, to leave behind only solidified regions of the photoresist (i.e., the exposed regions of a negative photoresist or the unexposed regions of a positive photoresist).

Structure 210 is formed by providing a sacrificial layer 212 over the patterned resist layer 208. In various embodiments, the sacrificial layer provides a removable spacer of any appropriate dimensions that, although sometimes referred to as a “layer,” is not limited to being a substantially planar stratified zone. Suitable materials for the sacrificial layer 212 include, but are not limited to, materials known in the art to be removable by wet etching or dry etching. Materials removable by wet etch include, for example, salts and oxides. Materials removable by dry etch include, but are not limited to, metals, such as, for example, gold, molybdenum, titanium, copper, platinum, silver, tungsten, and chromium, and semiconductors, such as, for example, silicon, gallium arsenide, and germanium.

In at least some embodiments, a region of the sacrificial material of layer 212 later provides a template for the tunnel being manufactured. The template defines the shape of the tunnel passage, and the tunnel passage is created by removing the template, while leaving at least substantially intact the substrate 202 and a covering layer that define the surrounding tunnel structure. In such embodiments, the material of the sacrificial layer 212 is chosen to facilitate its later removal while leaving the surrounding structure at least substantially intact. In particular embodiments, the material for the sacrificial layer 212 is chosen to be differently soluble from the substrate 202 and the material chosen to form a covering layer over the final tunnel structure. This allows for dissolution of the sacrificial material to hollow out a tunnel passage, while leaving the substrate 202 and covering layer at least substantially intact. For example, the sacrificial layer 212 is made from an acetone-soluble photoresist, and acetone is used to hollow out a tunnel passage, while leaving at least substantially intact the substrate 202 and a covering layer made of a non-acetone soluble material such as, for example, spin-on glass.

In certain embodiments, the sacrificial layer 212 is made of a metal, such as, for example, gold, molybdenum, titanium, copper, platinum, silver, tungsten, or chromium. One non-limiting example of a particularly useful material for the sacrificial layer 212 is tungsten. Such a sacrificial layer 212 is patterned to provide tungsten tunnel templates that anneal when the complex is baked at a high temperature, for example, during annealing of a covering layer of spin-on glass. Metal sacrificial layers are particularly useful in forming long tunnels, e.g., on a wafer scale.

Another non-limiting example of a useful material for the sacrificial layer 212 is germanium, which is removable by conversion under oxidizing conditions to germanium oxide, followed by removal by sublimation at a temperature below about 400° C. or at reduced temperature in vacuo. Still other suitable materials for the sacrificial layer 212 include polymers that dissipate into the surrounding layers upon heating. Non-limiting examples include organic polymers, such as, for example, norbornene-type polymers, methacrylates, and epoxies. In certain embodiments, such polymers are used to provide an enclosed sacrificial template that decomposes on heating to leave a completely closed interior volume, without requiring any access openings for passage of, for example, etching solvents or dissolved sacrificial material. Such embodiments allow for production of an article defining a fully enclosed passage, which is accessible by one or more later-created openings. However, the gaseous decomposition products generated upon heating of the sacrificial polymer material diffuse into the neighboring layers, so that the surrounding structure in the product article is impregnated with polymer decomposition products. In some embodiments, a polymer sacrificial layer and its decomposition by heating are not employed, so that the final article is substantially free from polymer decomposition products.

The patterned resist layer 208 and the portions of sacrificial layer 212 resting thereon are removed to afford structure 214, including the substrate 202 and a patterned sacrificial layer 216. In at least some embodiments, removal is achieved via a lift off procedure. Such procedures are well known in the art, and include dissolution of the resist material, thereby removing the patterned resist layer 208 itself, as well as the portions of the sacrificial layer 212 resting thereon. The resulting patterned sacrificial layer 216 serves as a tunnel template, defining the shape and location of a tunnel passage.

Structure 218 is formed by providing a layer of spin-on glass 220 over the patterned sacrificial layer 216 and the substrate 202. Annealing is used to convert at least a region of the spin-on glass layer 220 to form a covering layer that will surround and define a tunnel. In certain embodiments, a mask is used to define one or more particular regions of the spin-on glass for annealing. The tunnel template 216 is removed to form structure 222 having a tunnel 224. Methods of removing the sacrificial material include, for example, wet etching and dry etching procedures. As a non-limiting example, the sacrificial tunnel template layer 216 is removed by dissolution in a solvent that leaves the substrate 202 and annealed spin-on glass 220 at least substantially intact.

In certain embodiments, as shown in FIG. 2B, removal of the sacrificial tunnel template layer 216 is facilitated by the creation of one or more access openings 226 in the covering layer 220 that extend to and are in fluid communication with the sacrificial layer 216. Such access openings 226 are used, for example, to expose the sacrificial layer 216 to solvent or wet etch, and to facilitate removal of the sacrificial material. Once the sacrificial layer 216 has been removed, the access openings 226 are either left open or are closed, depending on the application.

After removal of the sacrificial layer 216, the tunnel passage 224 is formed by the resulting space between the substrate 202 and the covering layer of annealed spin-on glass 220. In alternative embodiments, the covering layer is formed from a material other than spin-on glass. An insulator, semiconductor, or metal material is chosen to provide the desired properties in the covering layer and to be differently soluble, etchable, etc., from the sacrificial layer so that the sacrificial layer is removable while leaving the covering layer at least substantially intact.

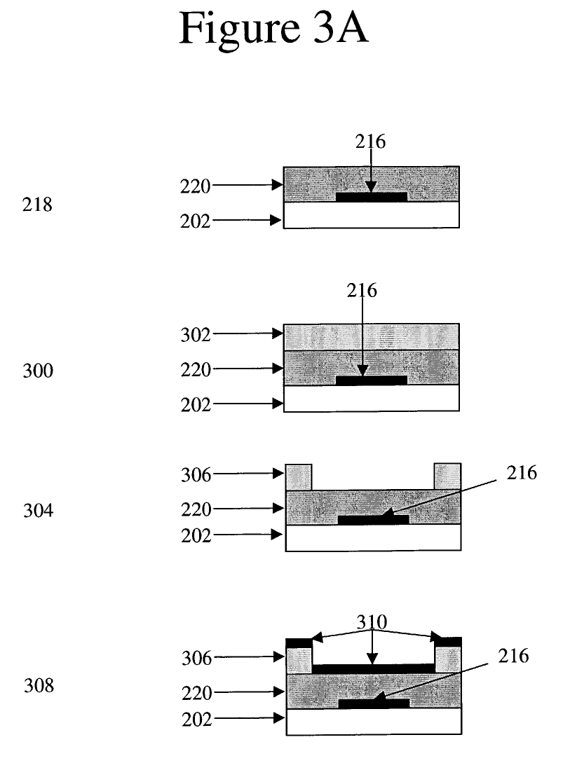

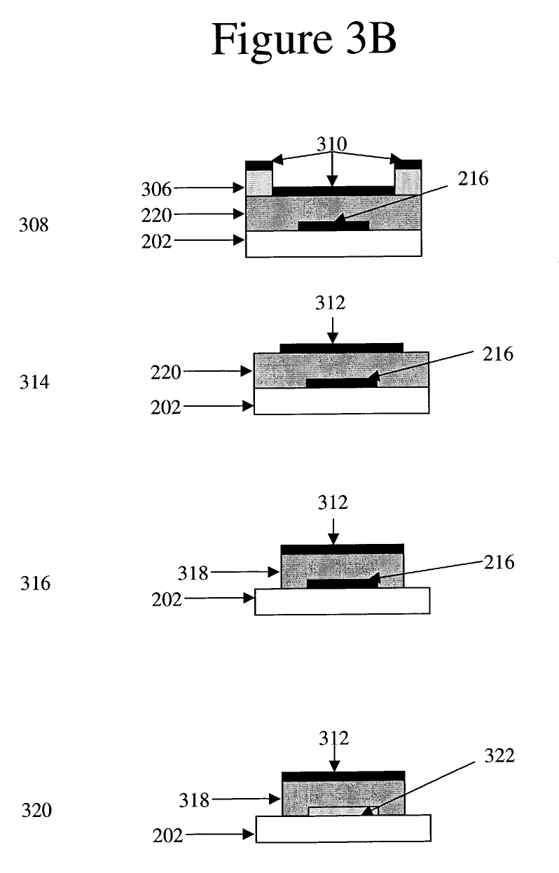

FIGS. 3A-B illustrate another method of creating nanoscopic tunnels. A structure 218 is provided, as described above, including a substrate 202, a tunnel template 216, and a layer of annealed spin-on glass 220. Structure 300 is formed by providing a layer of resist 302 over the annealed spin-on glass 220. The layer of resist 302 is patterned, for example, by using lithography to expose one or more selected sections of the resist 302. Suitable substrate materials, resist materials, and lithographic techniques are well known in the art, as described above. Structure 304 having patterned resist layer 306 is formed, for example, by removing the desired portions of the lithographically treated resist 302 using standard techniques known in the art. As a non-limiting example, resist 302 is a photoresist, the exposed portions of which are dissolved with a solvent that leaves the annealed spin-on-glass 220 and unexposed portions of the photoresist at least substantially intact.

Structure 308 is formed by providing a mask layer 310 above the patterned resist layer 306 and the annealed spin-on glass 220. In at least some embodiments, the mask 310 is made from a material capable of being etched selectively over silicon oxide. Non-limiting examples of useful mask materials include metals, such as titanium, platinum, tungsten, chromium, and molybdenum, and silicon nitride.

The patterned resist layer 306 and the areas of mask 310 overlying it are removed. In at least some embodiments, removal is accomplished using a lift off procedure. Such procedures are well known in the art, as described above. After the removal step, a patterned layer of mask 312 remains on the annealed spin-on glass 220, forming a structure 314.

The annealed spin-on glass 220 not covered by the patterned mask 312 is removed, for example, by etching, thus forming a structure 316 having a patterned layer of spin-on-glass 318. Suitable etching techniques are known in the art and include, but are not limited to, reactive ion etching with CHF₃, CF₄, or Cl₂. In some embodiments, as shown in structures 316 and 320, the patterned mask 312 is left in place. Alternatively, the mask is removed without damaging the underlying structure. Mask removal is accomplished, for example, by an appropriate stripper or lift off process, including removal by solvents in a wet process or by gases in a dry process. The sacrificial tunnel template layer 216 is removed to form a structure 320 having a tunnel 322 in the resulting space between the substrate 202 and the covering layer of annealed spin-on glass 318. Suitable materials for the sacrificial tunnel template layer 216 and methods for removing it are known in the art, as described above.

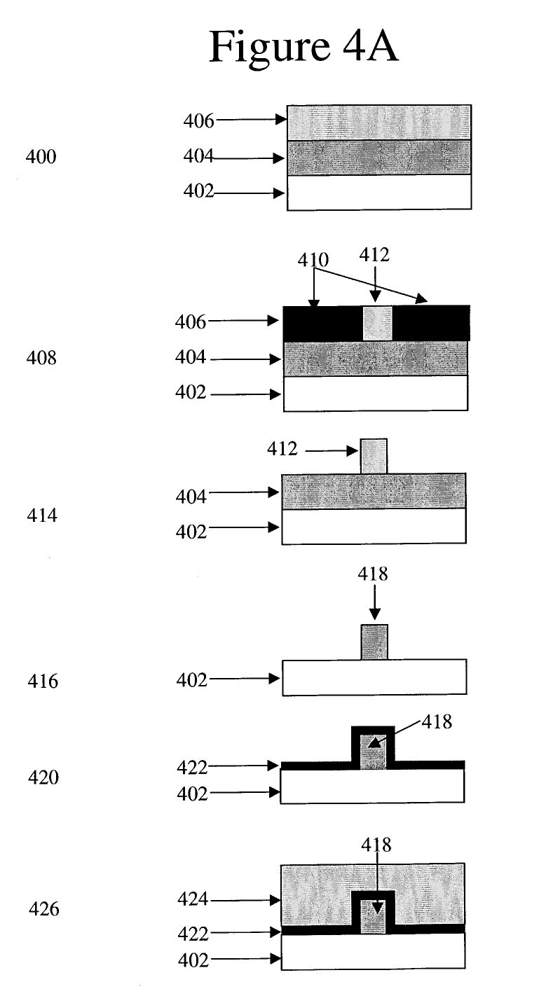

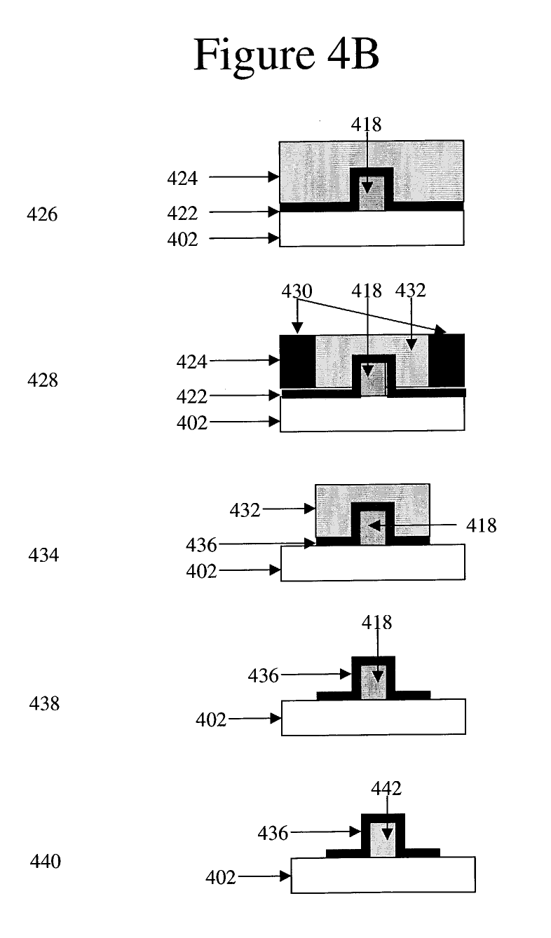

FIGS. 4A-B illustrate yet another method of creating nanoscopic tunnels. Advantageously, this method does not require the presence of silicon or silicon oxide on the surface of the final product, thus allowing for selection of surface material(s) based on the desired physical properties of the final product. According to the method, a structure 400 is provided, including a substrate 402 covered by a sacrificial layer 404 and a resist layer 406. Suitable materials for the substrate 402, the sacrificial layer 404, and the resist layer 406 are as described above. In particular embodiments, the sacrificial layer 404 is made of a material that is removable by wet etching and differs in solubility from the resist 406 and the substrate 402, thus allowing for later removal of the sacrificial layer 404 by dissolution while leaving the rest of the structure at least substantially intact.

The resist 406 is patterned, for example, using standard lithographic techniques. In the illustrated embodiment, lithography is used to form a structure 408, wherein portions 410 of the resist 406 are non-solidified, and portions 412 of the resist 406 are solidified. The non-solidified resist portions 410 are removed, leaving behind only the solidified resist portions 412 as shown in structure 414. The pattern of the resist 412 is transferred into the underlying sacrificial layer 404, for example, by etching, to produce structure 416 having a patterned sacrificial layer 418. Suitable etching techniques, such as, for example, wet etching and reactive ion etching, are well-known in the art. The resulting patterned sacrificial layer 418 provides a template for a tunnel.

Structure 420 is formed by providing a mask 422 over the tunnel template 418 and the substrate 402. The mask material is chosen to be compatible with later removal of the sacrificial layer 418. In at least some embodiments, the mask material differs in solubility from the material of the sacrificial layer 418, allowing for dissolution of the tunnel template 418 without disturbing the mask 422. In particular embodiments, the mask material is selected to create nanoscopic tunnels that are reactive or non-reactive as desired. As a non-limiting example, in one embodiment, the materials defining a nanoscopic tunnel for use in growing nanotubes are chosen to be suitable for high temperature reductive gas flow. Useful mask materials include, but are not limited to, metals and silicon oxide.

A layer of resist 424 is applied over the mask 422 to produce structure 426. In certain embodiments, the same material is used for resist layer 424 as was used for resist layer 406. In other embodiments, the resist layers 406 and 424 are made from different materials.

The resist layer 424 is patterned, for example, by lithography. In the illustrated embodiment, a structure 428 is formed, wherein portions 430 of the resist layer 424 are non-solidified, and portions 432 of the resist layer 424 are solidified. The non-solidified resist portions 430 are removed, for example, by dissolution, leaving behind the solidified resist portions 432. The regions of the mask 422 that are not covered by the solidified resist 432 are removed, for example, by an etching procedure, such as reactive ion etching or wet etching. The resulting structure 434 includes the solidified resist 432, and the region of mask 436 lying thereunder.

The solidified resist portions 432 are removed, for example, using strippers or dry removal, thus forming structure 438. The tunnel template 418 is then removed to form structure 440 having a tunnel 442 defined by the resulting space between the substrate 402 and the covering layer of mask 436. The tunnel template 418 is removed by any suitable method that leaves the substrate 402 and the covering layer of mask 436 at least substantially intact to surround the tunnel passage 442, as discussed above. In certain embodiments, an access opening is formed through the covering layer 436 to facilitate removal of the tunnel template 418.

One particularly interesting aspect of the nanoscopic tunnels described herein is the ability to create extremely long tunnels, e.g., wafer scale. Another interesting aspect is to create a tunnel in which one dimension is as fine as thin film limits. For example, several embodiments have a height on the order of nanometers, resulting from thin film deposition or growth of the sacrificial layer material.

Several of the above embodiments utilize metals, such as, for example, gold, molybdenum, titanium, copper, platinum, silver, tungsten, or chromium, to form a sacrificial layer. These embodiments were described in connection with creating nanoscopic tunnels. However, these novel sacrificial layer techniques are useful in creating other structures as well. For example, metal sacrificial layers are particularly useful in creating structures whose formation entails the removal of a relatively long sacrificial layer. However, any structure or device whose formation includes removal of a sacrificial layer will benefit.

It will be further appreciated that the scope of the present invention is not limited to the above-described embodiments, but rather is defined by the appended claims, and that these claims will encompass modifications of and improvements to what has been described.

What is claimed is:

1. An article defining a nanoscopic covered passage having a first end, a second end, and an opening at each end.

2. The article of claim 1, wherein the passage has a width between about 20 nm and about 200 nm and a height between about 1 nm and about 200 nm.

3. The article of claim 2, wherein the passage has a width between about 20 nm and about 100 nm and a height between about 1 nm and about 100 nm.

4. The article of claim 1, wherein the passage has a length between about 20 nm and about 12 inches.

5. The article of claim 4, wherein the passage has a length between about 1 μm and about 12 inches.

6. The article of claim 5, wherein the passage has a length between about 5 μm and about 12 inches.

7. The article of claim 6, wherein the passage has a length of about 4 inches.

8. The article of claim 1, wherein the passage is located in a semiconductor wafer.

9. The article of claim 1, wherein the passage is located on a semiconductor wafer.

10. The article of claim 1, wherein the passage defines a three-dimensional path.

11. The article of claim 1, wherein the passage and has a transverse cross-section with a controlled height and width.

12. The article of claim 11, wherein the height and width are each respectively substantially uniform over the entire passage.

13. The article of claim 11, wherein the passage is tapered.

14. The article of claim 1, comprising a substrate, a covering layer resting on the substrate, and a space between the covering layer and the substrate, wherein the space between the covering layer and the substrate defines the passage.

15. The article of claim 14, wherein the passage is embedded by the covering layer.

16. The article of claim 14, wherein the passage is raised above the substrate.

17. The article of claim 14, wherein the passage defines a path that is not perpendicular to a major surface of the substrate.

18. The article of claim 14, wherein the substrate comprises a semiconductor.

19. The article of claim 18, wherein the substrate is a semiconductor wafer and the passage has a length approximately equal to the length of the wafer.

20. The article of claim 14, wherein the substrate comprises silicon dioxide.

21. The article of claim 14, wherein the substrate comprises a metal oxide.

22. The article of claim 14, wherein the covering layer comprises a metal.

23. The article of claim 14, wherein the covering layer comprises silicon oxide.

24. An article defining a tunnel having a width between about 20 nm and about 200 nm and a height between about 1 nm and about 200 nm, wherein the width and the height are controlled.

25. The article of claim 24, wherein the tunnel has a width between about 20 nm and about 100 nm and a height between about 1 nm and about 100 nm.

26. The article of claim 24, wherein the tunnel has a length between about 20 nm and about 12 inches.

27. The article of claim 26, wherein the tunnel has a length between about 1 μm and about 12 inches.

28. The article of claim 27, wherein the tunnel has a length between about 5 μm and about 12 inches.

29. The article of claim 28, wherein the tunnel has a length of about 4 inches.

30. The article of claim 24, wherein the height and width are each respectively substantially uniform over the entire tunnel.

31. The article of claim 24, wherein the tunnel is tapered.

32. The article of claim 24, comprising a substrate, a covering layer resting on the substrate, and a space between the covering layer and the substrate, wherein the space between the covering layer and the substrate defines the tunnel.

33. The article of claim 32, wherein the tunnel is embedded by the covering layer.

34. The article of claim 32, wherein the tunnel is raised above the substrate.

35. The article of claim 32, wherein the tunnel defines a path that is not perpendicular to a major surface of the substrate.

36. The article of claim 32, wherein the substrate comprises a semiconductor.

37. The article of claim 36, wherein the substrate is a semiconductor wafer and the tunnel has a length approximately equal to the length of the wafer.

38. The article of claim 32, wherein the substrate comprises silicon dioxide.

39. The article of claim 32, wherein the substrate comprises a metal oxide.

40. The article of claim 32, wherein the covering layer comprises a metal.

41. The article of claim 32, wherein the covering layer comprises silicon oxide.

42. An article comprising a substrate, a covering layer resting on the substrate, and a space between the covering layer and the substrate, wherein the covering layer and the substrate are each respectively substantially homogeneous materials, and wherein the space between the covering layer and the substrate defines a nanoscopic tunnel having a transverse cross-section with a controlled height and width.
